(19) United States
(12) Patent Application Publication
(10) Pub. No.: US 2005/0266633 A1
(43) Pub. Date: Dec. 1, 2005

(54) Method for fabricating capacitor

(76) Inventor: Jing-Horng Gau, Hsinchu Hsien (TW)

Correspondence Address: J C PATENTS, INC., 4 VENTURE, SUITE 250, IRVINE, CA, 92618, US

(21) Appl. No.: 10/856,001

(22) Filed: May 28, 2004

(51) Int. Cl. H01L 21/8234; H01L 21/44

(52) U.S. Cl. 438/238

(57) ABSTRACT

A method for fabricating a capacitor is described. A metal layer is formed on a substrate, and then an insulating layer is formed over the substrate covering the metal layer. At least one opening is formed in the insulating layer exposing a portion of the metal layer, and a metal spacer is formed on the sidewall of the opening, wherein the metal spacer and the metal layer together constitute a lower electrode. A dielectric layer is formed on the lower electrode, and then an upper electrode is formed on the dielectric layer.

### BACKGROUND OF THE INVENTION

1. Field of the Invention

The present invention relates to a semiconductor process. More particularly, the present invention relates to a method for fabricating a capacitor, and an integrated capacitor and interconnect process based on the same method.

2. Description of the Related Art

MIM (metal/insulator/metal) capacitors are widely applied in mixed-mode or RF integrated circuits, and therefore take a large proportion of the lateral area in them. A conventional MIM capacitor is fabricated by sequentially stacking a first metal layer, a dielectric layer and a second metal layer on the substrate. The first metal layer, i.e., the lower electrode, usually has a planar shape so that the capacitance of the MIM capacitor is limited.

Though the capacitance limitation can be overcome by increasing the lateral area of the MIM capacitor, such a solution inevitably prevents miniaturization of the integrated circuits. Moreover, increasing the dielectric constant of the insulator between the lower and upper electrodes can also increase the capacitance, but fabricating a stable high-k dielectric film on the lower electrode is not so easy.

### SUMMARY OF THE INVENTION

In view of the foregoing, this invention provides a method for fabricating a capacitor that has a 3D structure and thereby provides larger capacitance.

This invention also provides an integrated capacitor and interconnect process that is based on the method for fabricating a capacitor of this invention.

The method for fabricating a capacitor of this invention is described as follows. A metal layer is formed on a substrate, and then an insulating layer is formed over the substrate covering the metal layer. At least one opening is formed in the insulating layer exposing a portion of the metal layer, and then a metal spacer is formed on the sidewall of the opening, wherein the metal spacer and the metal layer together constitute a lower electrode. A dielectric layer is formed on the lower electrode, and then an upper electrode is formed on the dielectric layer.

The integrated capacitor and interconnect process of this invention is the combination of the above method and an interconnect process. Specifically, a metal wiring line is formed together with the metal layer, and a via hole exposing a portion of the metal wiring line is formed in the insulating layer together with the opening exposing a portion of the metal layer. The width of the via hole is smaller than that of the opening, so that a metal plug can be formed in the via hole simultaneously with formation of the metal spacer on the sidewall of the opening. Then, an upper wiring line is formed together with the upper electrode to connect with the metal plug.

Since the lower electrode of the capacitor made with the above method includes at least one metal spacer, the inter-electrode area of the capacitor can be increased in the vertical direction to provide larger capacitance. In other words, the capacitor takes a smaller lateral area as compared with a conventional MIM capacitor that provides the same capacitance. Moreover, the method for fabricating a capacitor can be integrated with an interconnect process, so that the total number of fabricating steps is not increased.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1-6 illustrate a process flow of fabricating a capacitor according to a preferred embodiment of this invention in a cross-sectional view, while the capacitor fabricating process is integrated with an interconnect process.

### DESCRIPTION OF THE PREFERRED EMBODIMENTS

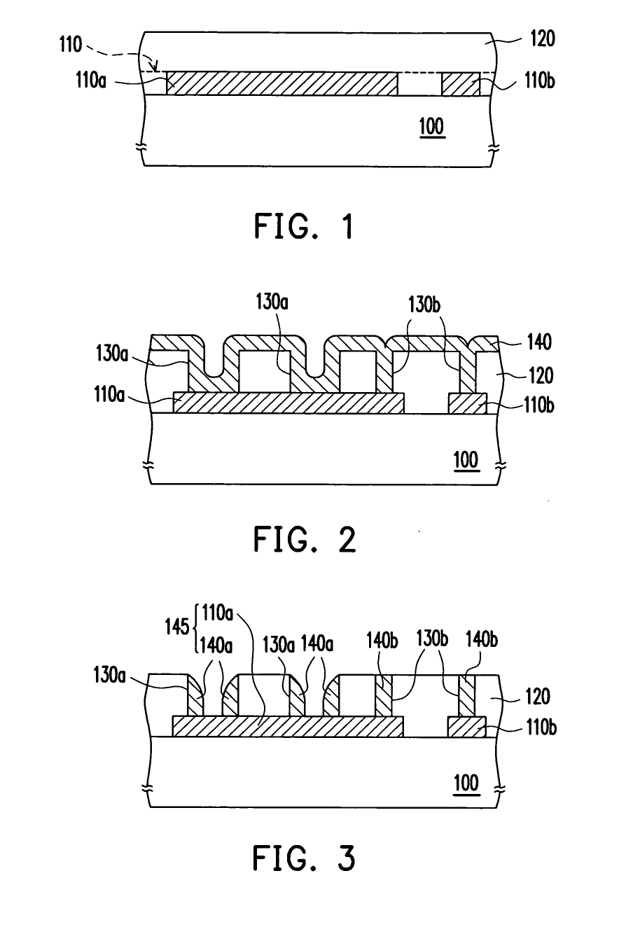

Referring to FIG. 1, a substrate 100 is provided, which may be a semiconductor substrate formed with semiconductor devices and interconnect structures thereon. A metal layer 110 is formed on the substrate 100, and then patterned into a lower electrode base plate 110a and a wiring line 110b. The material of the metal layer 110 is selected from the group consisting of Al, Cu, Ti, Ta, Mo and combinations thereof. Then, an intermetal dielectric (IMD) layer 120 is formed over the substrate 100 covering the lower electrode base plate 110a and the wiring line 110b. The EMD layer 120 may be further planarized if it is not formed to have a planar top surface. The material of the IMD layer 120 can be SiO₂ or a low-k material like FSG, aerogel, SILK or FLARE.

Referring to FIG. 2, openings 130a and via holes 130b are simultaneously formed in the insulating layer 120, wherein the openings 130a expose portions of the lower electrode base plate 110a, a via hole 130b exposes another portion of the lower electrode base plate 110a, and another via hole 130b exposes a portion of the wiring line 110b. In addition, the width of each via hole 130b is smaller than that of each opening 130a. Thereafter, a metal layer 140 is formed over the substrate 100. The metal layer 140 has such a thickness to be substantially conformal in the wider openings 130b but fill up the narrower via holes 130b. The material of the metal layer 140 is preferably tungsten (W).

Referring to FIG. 3, the metal layer 140 is anisotropically etched to form metal spacers 140a on the sidewalls of the openings 130a, while the metal layer 140 outside the openings 130a and the via holes 130b is also removed to form plugs 140b in the via holes 130b. The metal spacers 140a and the lower electrode base plate 110a together constitute a lower electrode of a MIM capacitor, while the lower electrode base plate 110a is also connected with a plug 140b.

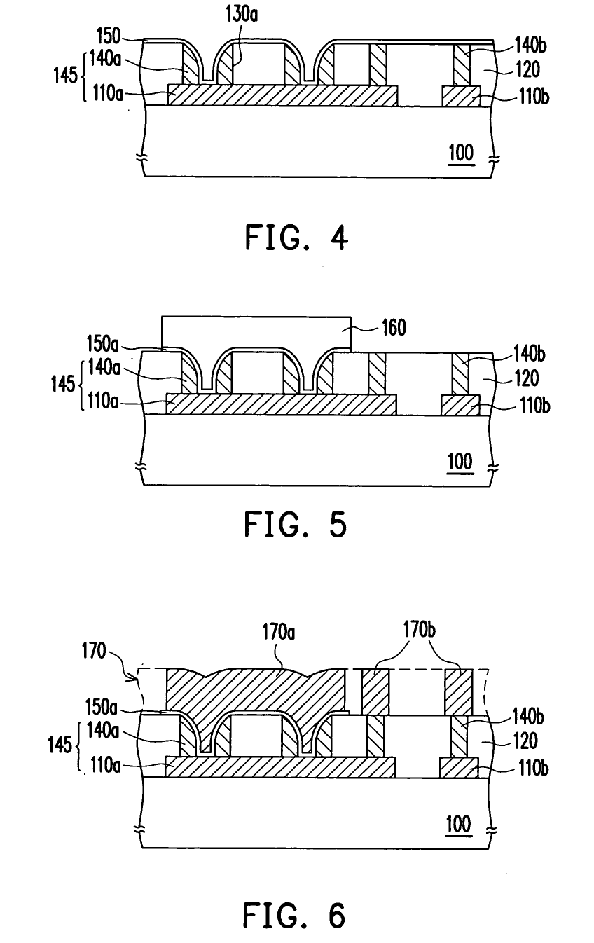

Referring to FIG. 4, a dielectric layer 150 is formed over the whole substrate 100. The material of the dielectric layer 150 is SiO₂, SiON, silicon nitride or a high-k material like barium strontium titanate (BST), lead zirconium titanate (PZT), Ta₂O₅ or TiO₂.

Referring to FIG. 5, a patterned photoresist layer 160 is formed on the dielectric layer 150 exposing portions of the dielectric layer 150 over the plugs 140b. The dielectric layer 150 is then patterned using the photoresist layer 160 as a mask, and the remaining dielectric layer 150a on the metal spacers 140a and the lower electrode base plate 110a serves as the insulator of the MIM capacitor.

Referring to FIG. 6, a metal layer 170 is formed over the substrate 100, and then patterned into an upper electrode 170a and wiring lines 170b. The upper electrode 170a is on the dielectric layer 150a separated from the lower electrode base plate 110a and the metal spacers 140a, and the wiring lines 170b are connected with the plugs 140b. In addition, the plug 140b and the wiring line 170b connected with the lower electrode base plate 110a are for controlling the MIM capacitor.

Since the lower electrode 145 of the capacitor made with the above method includes metal spacers 140a, the inter-electrode area of the capacitor can be increased in the vertical direction to provide larger capacitance. In other words, the capacitor takes a smaller lateral area as compared with a conventional MIM capacitor that provides the same capacitance. Moreover, since the method for fabricating a capacitor is integrated with an interconnect process in the preferred embodiment, the total number of fabricating steps is not increased.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims and their equivalents.

1. A process for fabricating a capacitor, comprising:
forming a first metal layer on a substrate;
forming an insulating layer over the substrate covering the first metal layer;
forming at least one opening in the insulating layer exposing a portion of the first metal layer;
forming a metal spacer on a sidewall of the opening, wherein the metal spacer and the first metal layer together constitute a lower electrode;
forming a dielectric layer on the lower electrode; and
forming an upper electrode on the dielectric layer.

2. The process of claim 1, wherein forming the metal spacer comprises:
forming a substantially conformal second metal layer over the substrate; and
anisotropically etching the second metal layer to form the metal spacer.

3. The process of claim 1, wherein the metal spacer comprises tungsten (W).

4. The process of claim 1, wherein the first metal layer comprises a material selected from the group consisting of Al, Cu, Ti, Ta, Mo and combinations thereof.

5. The process of claim 1, wherein the insulating layer comprises SiO₂ or a low-k material.

6. The process of claim 1, wherein the dielectric layer comprises SiO₂, SiON, silicon nitride or a high-k material.

7. The process of claim 1, wherein the upper electrode comprises a material selected from the group consisting of Al, Cu, Ti, Ta, Mo and combinations thereof.

8. An integrated capacitor and interconnect process, comprising:
simultaneously forming a first metal layer and a metal wiring line on a substrate;
forming an insulating layer covering the first metal layer and the metal wiring line;
forming, in the insulating layer, at least one opening exposing a portion of the first metal layer and a via hole exposing a portion of the metal wiring line, wherein a width of the via hole is smaller than a width of the opening;
simultaneously forming a metal spacer on a sidewall of the opening and a metal plug in the via hole, wherein the metal spacer and the first metal layer together constitute a lower electrode;
forming a dielectric layer on the lower electrode; and
simultaneously forming an upper electrode on the dielectric layer and an upper wiring line connected with the metal plug.

9. The integrated process of claim 8, wherein the step of simultaneously forming the metal spacer and the metal plug comprises:
forming a second metal layer over the substrate, the second metal layer having such a thickness to be substantially conformal in the opening but fill up the via hole; and
anisotropically etching the second metal layer to form the metal spacer and to remove the second metal layer outside the via hole to form the metal plug.

10. The integrated process of claim 8, wherein the step of forming a dielectric layer on the lower electrode comprises:
forming a blanket dielectric layer over the substrate;
forming a patterned photoresist layer over the substrate exposing the blanket dielectric layer on the metal plug; and
removing the blanket dielectric layer exposed by the photoresist layer.

11. The integrated process of claim 8, wherein the step of simultaneously forming the first metal layer and the metal wiring line comprises:
forming a third metal layer on the substrate; and
patterning the third metal layer into the first metal layer and the metal wiring line.

12. The integrated process of claim 8, wherein the step of simultaneously forming the upper electrode and the upper wiring line comprises:
forming a fourth metal layer over the substrate; and
patterning the fourth metal layer into the upper electrode and the upper wiring line.

13. The integrated process of claim 8, wherein the metal spacer and the metal plug comprise tungsten (W).

14. The integrated process of claim 8, wherein the first metal layer and the metal wiring line comprise a material selected from the group consisting of Al, Cu, Ti, Ta, Mo and combinations thereof.

15. The integrated process of claim 8, wherein the insulating layer comprises SiO₂ or a low-k material.

16. The integrated process of claim 8, wherein the dielectric layer comprises SiO₂, SiON, silicon nitride or a high-k material.

17. The integrated process of claim 8, wherein the upper electrode and the upper wiring line comprise a material selected from the group consisting of Al, Cu, Ti, Ta, Mo and combinations thereof.
